(19) United States
(12) Patent Application Publication
(10) Pub. No.: US 2025/0324603 A1
(43) Pub. Date: Oct. 16, 2025

(54) SEMICONDUCTOR DEVICES AND FABRICATING METHODS THEREOF AND MEMORIES

(71) Applicant: Yangtze Memory Technologies Co., Ltd., Wuhan (CN)

(72) Inventors: Teng HUANG, Wuhan (CN); Yanwei SHI, Wuhan (CN); Quan ZHANG, Wuhan (CN); Lu ZHOU, Wuhan (CN); Zhixian MENG, Wuhan (CN); Cheng CHEN, Wuhan (CN)

(21) Appl. No.: 19/177,478

(22) Filed: Apr. 11, 2025

(30) Foreign Application Priority Data
Apr. 15, 2024 (CN) 202410451687.4

(51) Int. Cl. H10B 43/40; H10B 41/41

(52) U.S. Cl. CPC H10B 43/40; H10B 41/41

(57) ABSTRACT

The present disclosure provides a semiconductor device, a fabrication method thereof and a memory. The method of forming the semiconductor device includes: providing a semiconductor structure which includes: a semiconductor layer with a first region; and a first gate insulation layer located on the first region; forming a first columnar structure covering a portion of the first gate insulation layer on the first gate insulation layer, wherein the first columnar structure includes a gate and a mask layer located on the gate; forming a spacing layer conformally covering the first columnar structure on the first region and the first gate insulation layer on both sides of the first columnar structure; removing a portion of the spacing layer, wherein the remaining spacing layer covers a side wall of the first columnar structure; removing the first gate insulation layer on both sides of the first columnar structure exposed.

### CROSS-REFERENCE TO RELATED APPLICATIONS

The present application claims the benefit of priority to Chinese Application No. 202410451687.4, filed on Apr. 15, 2024, which is hereby incorporated by reference in its entirety.

### TECHNICAL FIELD

The present disclosure relates to the field of semiconductor technology, and, in particular, to semiconductor devices, fabrication methods thereof and memories.

### BACKGROUND

With the rapid development of data storage technology, more and more data memory systems are appearing in electronic devices used by people, such as solid-state drives (SSDs). SSD has been widely used in military, automotive, industrial, medical, and aviation fields due to its fast read and write speed, vibration resistance, low power consumption, no noise, low heat, and light weight.

### SUMMARY

According to a first aspect of the disclosed implementation, a semiconductor device is provided. The semiconductor device may include a semiconductor structure, a gate and a spacing sidewall structure. The semiconductor structure may include a semiconductor layer with a first region and a first gate insulation layer located on the first region. The gate and the spacing sidewall structure located on the first gate insulation layer. The spacing sidewall structure may cover a side wall of the gate, and a first recess may exist at a portion of the spacing sidewall structure close to the first gate insulation layer.

In some examples, a size of the first recess along a direction perpendicular to a thickness direction of the semiconductor layer ranges from 1 nm to 10 nm.

In some examples, the spacing sidewall structure may include a first spacing material layer, a second spacing material layer, and a third spacing material layer. The first spacing material layer may cover the side wall of the gate. The second spacing material layer may include a first portion extending along a thickness direction of the semiconductor layer and a second portion extending along a direction perpendicular to the thickness direction of the semiconductor layer. The first portion may cover a side wall of the first spacing material layer, and the second portion may cover the first gate insulation layer on both sides of the gate. The third spacing material layer may cover a side wall of the first portion and a top wall of the second portion. The first recess is located at an end of the second portion between the first gate insulation layer and the third spacing material layer.

In some examples, a material of the first spacing material layer may include silicon oxide, a material of the second spacing material layer may include silicon nitride, and a material of the third spacing material layer may include silicon oxide.

In some examples, a second recess may exist at a top of the spacing sidewall structure.

In some examples, the semiconductor device may further include an electrode layer located on the gate and on the semiconductor layer on both sides of the first gate insulation layer.

In some examples, a material of the electrode layer may include nickel silicide.

In some examples, the semiconductor layer may further include a second region. The first region and the second region are arranged side by side along a direction perpendicular to a thickness direction of the semiconductor layer. The semiconductor structure may further include a second gate insulation layer located on the second region, and a thickness of the first gate insulation layer is greater than that of the second gate insulation layer.

In some examples, the gate and the spacing sidewall structure are further located on the second gate insulation layer. The gate on the first region and the gate on the second region are discrete from each other. The spacing sidewall structure on the first region and the spacing sidewall structure on the second region are discrete from each other.

In some examples, the semiconductor device may further include an isolation structure. The isolation structure divides the semiconductor layer into the first region and the second region.

In some examples, the second region may include a first sub-region and a second sub-region. The first sub-region is covered by the second gate insulation layer. The second sub-region is located on both sides of the first sub-region. A top surface of the first sub-region is higher than a top surface of the second sub-region.

In some examples, a height difference between the top surface of the first sub-region and the top surface of the second sub-region ranges from 5 nm to 15 nm.

In some examples, a material of the gate may include polycrystalline silicon.

In some examples, a material of the first gate insulation layer may include silicon oxide.

According to a second aspect of the disclosed implementation, a memory is provided. The memory may include a semiconductor device. The semiconductor device may include a semiconductor structure, a gate and a spacing sidewall structure. The semiconductor structure may include a semiconductor layer with a first region and a first gate insulation layer located on the first region. The gate and the spacing sidewall structure located on the first gate insulation layer. The spacing sidewall structure may cover a side wall of the gate, and a first recess may exist at a portion of the spacing sidewall structure close to the first gate insulation layer.

According to a third aspect of the disclosed implementation, a method of forming a semiconductor device is provided. The formation method may include providing a semiconductor structure. The semiconductor structure may include a semiconductor layer with a first region and a first gate insulation layer located on the first region. The method may include forming a first columnar structure covering a portion of the first gate insulation layer on the first gate insulation layer. The first columnar structure may include a gate and a mask layer located on the gate. The method may include forming a spacing layer conformally covering the first columnar structure on the first region and the first gate insulation layer on both sides of the first columnar structure. The method may include removing a portion of the spacing layer. The remaining spacing layer may cover a side wall of the first columnar structure The method may include removing the first gate insulation layer on both sides of the first columnar structure exposed.

In some examples, the mask layer may include a first material layer and a second material layer located on the first material layer, and wherein a material of the first material layer may include silicon oxide, and a material of the second material layer may include silicon nitride.

In some examples, the method may further include removing the mask layer through a wet etching process after removing the first gate insulation layer on both sides of the first columnar structure exposed.

In some examples, the forming a spacing layer conformally covering the first columnar structure on the first region and the first gate insulation layer on both sides of the first columnar structure may include performing a thermal oxidation treatment on a side wall of the gate to form a first spacing material layer on the side wall of the gate, wherein the mask layer, the first spacing material layer, and a remaining portion of the gate form a second columnar structure. The forming a spacing layer conformally covering the first columnar structure on the first region and the first gate insulation layer on both sides of the first columnar structure may include forming a second spacing material layer conformally covering the second columnar structure and the first gate insulation layer on both sides of the second columnar structure. The forming a spacing layer conformally covering the first columnar structure on the first region and the first gate insulation layer on both sides of the first columnar structure may include forming a third spacing material layer conformally covering the second spacing material layer.

In some examples, the removing the first gate insulation layer on both sides of the first columnar structure exposed may include thinning the first gate insulation layer on both sides of the first columnar structure exposed through a dry etching process. The removing the first gate insulation layer on both sides of the first columnar structure exposed may include removing the remaining first gate insulation layer on both sides of the first columnar structure through a wet etching process.

In some examples, the removing a portion of the spacing layer and the thinning the first gate insulation layer on both sides of the first columnar structure exposed through a dry etching process are carried out in a same process.

In some examples, the forming a first columnar structure covering a portion of the first gate insulation layer on the first gate insulation layer may include forming a gate material layer covering the first gate insulation layer on the first gate insulation layer. The forming a first columnar structure covering a portion of the first gate insulation layer on the first gate insulation layer may include forming a mask material layer covering the gate material layer on the gate material layer. The forming a first columnar structure covering a portion of the first gate insulation layer on the first gate insulation layer may include etching the mask material layer and the gate material layer to form the first columnar structure.

In some examples, the method may further include forming an electrode layer after removing the first gate insulation layer on both sides of the first columnar structure exposed. The electrode layer covers a top of the gate and the semiconductor layer on both sides of the gate.

In some examples, the semiconductor layer may further include a second region, and the first region and the second region are arranged side by side along a direction perpendicular to a thickness direction of the semiconductor layer. The semiconductor structure may further include a second gate insulation layer located on the second region, and a thickness of the first gate insulation layer is greater than that of the second gate insulation layer.

In some examples, the method may further include forming the first columnar structure covering a portion of the second gate insulation layer on the second gate insulation layer while forming the first columnar structure covering the portion of the first gate insulation layer on the first gate insulation layer. The method may further include forming the spacing layer conformally covering the first columnar structure on the second region and the second gate insulation layer on both sides of the first columnar structure on the second region while forming the spacing layer conformally covering the first columnar structure on the first region and the first gate insulation layer on both sides of the first columnar structure. The method may further include removing a portion of the spacing layer on the second region while removing the portion of the spacing layer on the first region, wherein the remaining spacing layer on the second region covers a side wall of the first columnar structure on the second region. The method may further include removing the second gate insulation layer on both sides of the first columnar structure exposed on the second region and a portion of the semiconductor layer on both sides of the first columnar structure on the second region while removing the first gate insulation layer on both sides of the first columnar structure exposed on the first region.

In some examples, the formation method may further include forming an isolation structure in the semiconductor layer, wherein the isolation structure divides the semiconductor layer into the first region and the second region.

In the technical solution provided in the present disclosure, on the one hand, after forming the gate in the first columnar structure, the mask layer on the gate is retained, and when removing a portion of the spacing layer and removing the first gate insulation layer on both sides of the first columnar structure, the mask layer can provide better protection for the gate, thereby improving the damage of high-energy plasma to the gate during the process of removing the portion of the spacing layer and the first gate insulation layer on both sides of the first columnar structure. Due to the protection for the gate by the mask layer, the removal of the portion of the spacing layer and the removal of the first gate insulation layer on both sides of the first columnar structure exposed can be carried out in the same etching process, thereby reducing the process flow and saving costs. Since the mask layer on the gate is a mask layer formed on the gate material layer during the process to form the gate by etching the gate material layer, an implementation of the present disclosure does not remove the mask layer after forming the gate, but retains the existing mask layer as a protective layer, thereby fully utilizing resources and fully saving costs while improving the problem of damage to the gate by high-energy plasma.

### BRIEF DESCRIPTION OF DRAWINGS

FIGS. 1 to 4 are structure diagrams of a formation process of a semiconductor device provided in an implementation of the present disclosure.

FIG. 5 is a flowchart diagram of a formation method of a semiconductor device provided in an implementation of the present disclosure.

FIGS. 6 to 15 are structure diagrams of a formation process of another semiconductor device provided in an implementation of the present disclosure.

FIG. 16 is a first cross-sectional structure diagram of a semiconductor device provided in an implementation of the present disclosure.

FIG. 17 is a second cross-sectional structure diagram of a semiconductor device provided in an implementation of the present disclosure.

FIG. 18 is a third cross-sectional structure diagram of a semiconductor device provided in an implementation of the present disclosure.

FIG. 19 is a structure diagram of a memory provided in an implementation of the present disclosure.

FIG. 20 is a structure diagram of a memory system provided in an implementation of the present disclosure.

### DETAILED DESCRIPTION

Example implementations of the present disclosure will be described hereafter in more detail with reference to the accompanying drawings. Although example implementations of the present disclosure are shown in the accompanying drawings, it should be understood that the present disclosure can be implemented in various forms and should not be limited by the specific implementations described herein. The implementations are provided to enable a more thorough understanding of the present disclosure and to fully convey the scope of the present disclosure to those skilled in the art.

In the following description, a large number of example details are provided to provide a more thorough understanding of the present disclosure. However, it is apparent to those skilled in the art that the present disclosure can be implemented without one or more of these details. In other examples, in order to avoid confusion with the present disclosure, some well-known technical features in this field have not been described; that is to say, not all the features of the actual implementations are described here, and the well-known functions and structures are not described in detail.

In the accompanying drawings, the same reference numbers represent the same components throughout.

It should be understood that spatial relationship terms such as “under”, “underneath”, “lower”, “below”, “above”, “upper”, etc., may be used here for convenience in describing the relationship between one component or feature and other components or features shown in the Figs. It should be understood that in addition to the orientation shown in the Figs., the spatial relationship terms also include different orientations of the devices in use and operation. For example, if the device in the drawings is turned over, then the component or feature described as “underneath” or “under” or “below” the other components or features will be oriented “on” other components or features. Therefore, the example terms “underneath” and “under” may include both upper and lower orientations. The device can be oriented otherwise (rotated 90 degrees or in other orientations) and the spatial description terms used here are explained accordingly.

The terms are used here only for the purpose of describing specific implementations, but not limiting the present disclosure. Terms herein, such as “a” “an” or “the” in singular usage can be understood to convey a plural usage as well, unless definitely stated otherwise in the context. It should also be understood that the terms “consisting of” and/or “including”, when used in this description, determine the presence of at least one of said features, integers, steps, operations, components, or members, but do not exclude the presence or addition of at least one of one or more other features, integers, steps, operations, components, members, or groups. When used here, the term “at least one of” includes any and all combinations of related listed items.

The peripheral circuit of three-dimensional NAND memory is an integrated circuit based on complementary metal oxide semiconductor (CMOS), which is designed and manufactured with respect to a field effect transistor (FET). There are two basic types of field-effect transistors, junction field effect transistor (JFET) and metal oxide semiconductor field effect transistor (MOSFET), wherein a gate in a MOSFET device, which serves as the input terminal of the field-effect transistor, is insulated from the other two electrodes of the transistor by a thin dielectric layer (referred to as a gate oxide layer, GOX).

Due to the inclusion of multiple MOSFET devices in CMOS integrated circuits, and the voltage applied to each MOSFET device being different in a high-voltage circuit, an ordinary analog circuit, and an input/output circuit, it is desired to balance and consider, in the design and manufacturing of CMOS, the case that the voltages applied to multiple MOSFET devices are different. The turn-on voltage of the gate (also known as a threshold voltage, VT) is affected by factors such as a thickness of the gate oxide layer. The gate oxide layer is configured to induce different electric fields and apply them to a surface of the channel, so that minority carriers of the substrate are adsorbed and accumulated onto the surface of the channel and inverted, thereby achieving conduction between the source and drain. Therefore, in the design and manufacturing of CMOS, the gate oxide layers in MOSFET devices are set to different thicknesses. In this way, the gate oxide layers of different thicknesses induce induced channels of different voltages and invert them, so that the threshold voltages VT are different. In some examples, in the peripheral circuits of NAND 3D memory, in order to balance the high-voltage circuit, the ordinary analog circuit, and the input-output circuit, it is desired to set gate oxide layers with a large thickness difference. The large difference in gate oxide layer thickness brings a challenge to process integration.

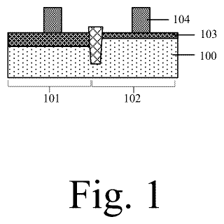

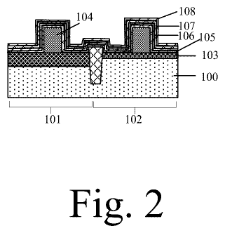

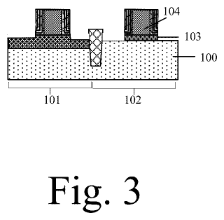

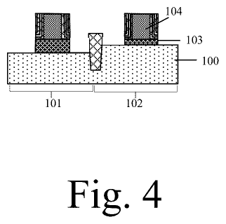

In some implementations, as shown in FIGS. 1 to 4, the substrate 100 includes a high voltage region 101 and a low voltage region 102. A gate oxide layer 103 is formed on both the high voltage region 101 and the low voltage region 102, and the gate oxide layer 103 formed on the high voltage region 101 is thicker than the gate oxide layer 103 formed on the low voltage region 102. After forming a silicon column 104 on the high voltage region 101 and the low voltage region 102, a first silicon oxide layer 105, a first silicon nitride layer 106, a second silicon oxide layer 107, and a second silicon nitride layer 108 are formed to cover the silicon column 104 in a conformal manner. Next, the same mask is employed for the first dry etching treatment to remove the first silicon oxide layer 105, the first silicon nitride layer 106, the second silicon oxide layer 107, and the second silicon nitride layer 108 at the top of the silicon column 104, as well as portions of the first silicon oxide layer 105, the first silicon nitride layer 106, the second silicon oxide layer 107, and the second silicon nitride layer 108 on both sides of the silicon column 104, and to remove the gate oxide layer 103 on both sides of the silicon column 104 on the low voltage region 102 and a portion of the gate oxide layer 103 on both sides of the silicon column 104 on the high voltage region 101 are also removed. Due to the thickness of the gate oxide layer 103 on the high voltage region 101 being greater than that on the low voltage region 102, after the gate oxide layer 103 on both sides of the silicon column 104 on the low voltage region 102 is removed completely, the gate oxide layer 103 on both sides of the silicon column 104 on the high voltage region 101 is still very thick, and additional etching is desired to remove the gate oxide layer 103 on both sides of the silicon column 104 on the high voltage region 101, so that the substrate 100 on both sides of the silicon column 104 on the high voltage region 101 is exposed to prepare for the formation of an electrode layer on the substrate 100 on both sides of the silicon column 104. In order to prevent damage to the silicon column 104 on the low voltage region 102, after the gate oxide layer 103 on both sides of the silicon column 104 on the low voltage region 102 is removed completely, a mask is employed for photolithography, the structure on the low voltage region 102 is covered and the gate oxide layer 103 on both sides of the silicon column 104 on the high voltage region 101 is subjected to a second dry etching treatment to remove the remaining gate oxide layer 103 on both sides of the silicon column 104 on the high voltage region 101.

In the scheme provided by the above implementations, on the one hand, in order to balance the different thicknesses of gate oxide layer on the high voltage region and the low voltage region, an additional operation of second dry etching is desired after the first dry etching, and an additional photolithography process is desired, which consumes an additional mask and results in a complex process and high cost. During the first and second dry etchings, high-energy plasma during the dry etching can easily cause plasma induced damage (PID) to the silicon column exposed, thereby affecting the performance of the device.

In view of one or more of the above issues, an implementation of the present disclosure provides a formation method of a semiconductor device.

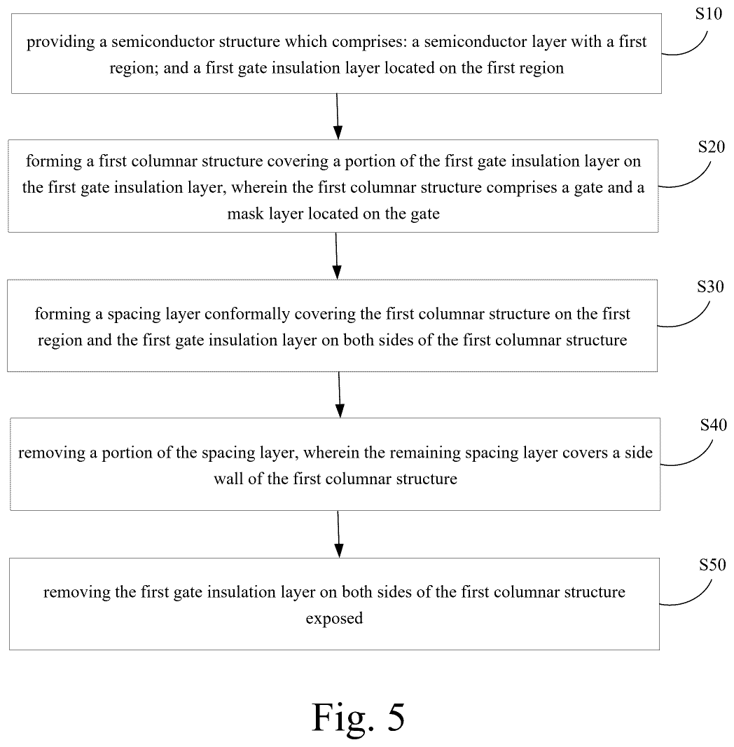

FIG. 5 is a flowchart of a formation method of a semiconductor device according to an implementation disclosed herein. As shown in FIG. 5, the formation method includes at least the following operations.

S10: Providing a semiconductor structure; wherein the semiconductor structure includes a semiconductor layer with a first region and a first gate insulation layer located on the first region.

S20: Forming a first columnar structure covering a portion of the first gate insulation layer on the first gate insulation layer; wherein the first columnar structure including a gate and a mask layer located on the gate.

S30: Forming a spacing layer conformally covering the first columnar structure on the first region and the first gate insulation layer on both sides of the first columnar structure.

S40: Removing a portion of the spacing layer, wherein the remaining spacing layer covers a side wall of the first columnar structure.

S50: Removing the first gate insulation layer on both sides of the first columnar structure exposed.

The operations shown in FIG. 5 are not exclusive, and other operations can be performed before, after, or between any of the operations in the illustrated operations. The operations shown in FIG. 5 can be adjusted in order according to actual needs.

In an implementation of the present disclosure, on the one hand, after forming the gate in the first columnar structure, the mask layer on the gate is retained, and when removing a portion of the spacing layer and removing the first gate insulation layer on both sides of the first columnar structure, the mask layer can provide better protection for the gate, thereby improving the damage of high-energy plasma to the gate during the process of removing the portion of the spacing layer and the first gate insulation layer on both sides of the first columnar structure. Due to the protection for the gate by the mask layer, the removal of the portion of the spacing layer and the removal of the first gate insulation layer on both sides of the first columnar structure exposed can be carried out in the same etching process, thereby reducing the process flow and saving costs. Since the mask layer on the gate is a mask layer formed on the gate material layer during the process to form the gate by etching the gate material layer, an implementation of the present disclosure does not remove the mask layer after forming the gate, but retains the existing mask layer as a protective layer, thereby fully utilizing resources and fully saving costs while improving the problem of damage to the gate by high-energy plasma.

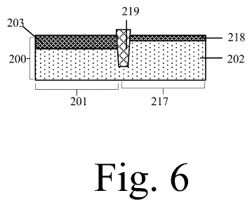

FIGS. 6 to 15 are diagrams of the formation process of a semiconductor device shown in an implementation of the present disclosure. The following will provide an example explanation of the formation method of the semiconductor device provided in an implementation of the present disclosure, in conjunction with FIGS. 5, 6, and 15.

In operation S10, as shown in FIG. 6, it is mainly to provide a semiconductor structure 200. The semiconductor structure 200 includes: a semiconductor layer 202 with a first region 201; and a first gate insulation layer 203 located on the first region 201.

In some implementations, as shown in FIG. 6, the semiconductor layer 202 also has a second region 217, wherein the first region 201 and the second region 217 are arranged side by side along a direction perpendicular to a thickness direction of the semiconductor layer 202. The semiconductor structure 200 further includes a second gate insulation layer 218 located on the second region 217, wherein a thickness of the first gate insulation layer 203 is greater than that of the second gate insulation layer 218.

In some examples, the semiconductor layer 202 may include a substrate, which may include a single semiconductor material substrate (such as silicon (Si) substrate, germanium (Ge) substrate, etc.), a composite semiconductor material substrate (such as germanium silicon (SiGe) substrate, etc.), a silicon on insulator (SOI) substrate, a germanium on insulator (GeOI) substrate, etc. For example, the substrate is a silicon substrate. The first region 201 of the semiconductor layer 202 can be a high voltage region, and the second region 217 can be a low voltage region. In some examples, the materials of the first gate insulation layer 203 and the second gate insulation layer 218 are the same. The materials of the first gate insulation layer 203 and the second gate insulation layer 218 include but are not limited to silicon oxide.

In some implementations, as shown in FIG. 6, the method further includes: forming an isolation structure 219 in the semiconductor layer 202, which divides the semiconductor layer 202 into the first region 201 and the second region 217.

In some examples, the material of the isolation structure 219 includes but is not limited to insulation material. For example, the material of the isolation structure 219 is silicon oxide. The semiconductor layer 202 can be etched to form a trench in the semiconductor layer 202, and an insulating material can be deposited in the trench to form the isolation structure 219 mentioned above.

In an implementation of the present disclosure, the deposition process includes but is not limited to chemical vapor deposition (CVD), low pressure chemical vapor deposition (LPCVD), plasma enhanced chemical vapor deposition (PECVD), physical vapor deposition (PVD), and atomic layer deposition (ALD).

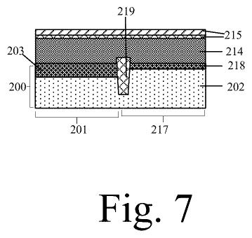

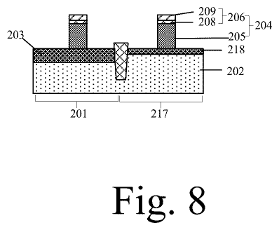

In operation S20, as shown in FIGS. 7 and 8, it is mainly to form, on the first gate insulation layer 203, a first columnar structure 204 covering a portion of the first gate insulation layer 203. The first columnar structure 204 includes a gate 205 and a mask layer 206 located on the gate 205.

In some implementations, as shown in FIG. 7, the forming a first columnar structure 204 covering a portion of the first gate insulation layer 203 on the first gate insulation layer 203 includes: forming a gate material layer 214 covering the first gate insulation layer 203 on the first gate insulation layer 203; forming a mask material layer 215 covering the gate material layer 214 on the gate material layer 214; etching the mask material layer 215 and the gate material layer 214 to form the first columnar structure 204, as shown in FIG. 8.

In some examples, the gate material layer 214 mentioned above and the mask material layer 215 mentioned above can be formed by deposition process, and the mask material layer 215 and the gate material layer 214 can be etched by dry etching process to form the first columnar structure 204 mentioned above.

In some examples, the material of the gate material layer 214 includes but is not limited to at least one of polycrystalline silicon, a doped semiconductor material (such as doped silicon, doped germanium, etc.), a conductive metal nitride (such as titanium nitride, tantalum nitride, etc.), a metal material (such as tungsten, titanium, tantalum, etc.), and a metal semiconductor compound (such as tungsten silicide, cobalt silicide, titanium silicide, etc.).

In some implementations, as shown in FIG. 8, the mask layer 206 includes a first material layer 208 and a second material layer 209 located on the first material layer 208. The material of the first material layer 208 includes silicon oxide, and the material of the second material layer 209 includes silicon nitride.

In some implementations, as shown in FIGS. 7 and 8, the method further includes: while forming a first columnar structure 204 covering a portion of the first gate insulation layer 203 on the first gate insulation layer 203, forming the first columnar structure 204 covering a portion of the second gate insulation layer 218 on the second gate insulation layer 218.

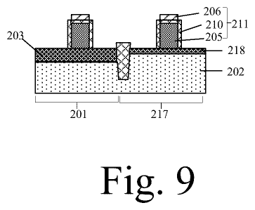

In operation S30, as shown in FIGS. 9 to 11, it is mainly to form a spacing layer 207 conformally covering the first columnar structure 204 on the first region 201 and the first gate insulation layer 203 on both sides of the first columnar structure 204.

In some implementations, as shown in FIGS. 9 to 11, while forming a spacing layer 207 conformally covering the first columnar structure 204 on the first region 201 and the first gate insulation layer 203 on both sides of the first columnar structure 204, the spacing layer 207 is also formed to conformally covering the first columnar structure 204 on the second region 217 and the second gate insulation layer 218 on both sides of the first columnar structure 204 on the second region 217.

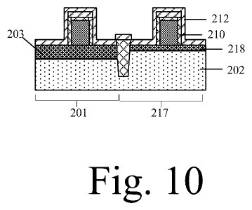

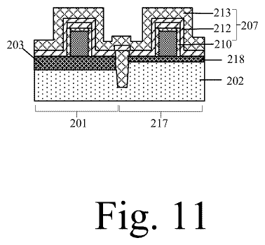

In some implementations, the forming a spacing layer 207 conformally covering the first columnar structure 204 on the first region 201 and the first gate insulation layer 203 on both sides of the first columnar structure 204 includes: as shown in FIG. 9, performing thermal oxidation treatment on a side wall of the gate 205 to form a first spacing material layer 210 on the side wall of the gate 205, wherein the mask layer 206, the first spacing material layer 210, and the remaining portion of the gate 205 form a second columnar structure 211; as shown in FIG. 10, forming a second spacing material layer 212 conformally covering the second columnar structure 211 and the first gate insulation layer 203 on both sides of the second columnar structure 211; as shown in FIG. 11, forming a third spacing material layer 213 conformally covering the second spacing material layer 212.

In some examples, the second spacing material layer 212 and the third spacing material layer 213 can be formed through a deposition process. A material of the first spacing material layer 210 includes but is not limited to silicon oxide, a material of the second spacing material layer 212 includes but is not limited to silicon nitride, and a material of the third spacing material layer 213 includes but is not limited to silicon oxide.

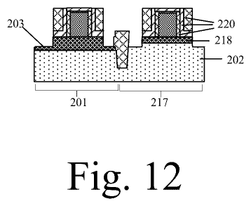

In operation S40, as shown in FIG. 12, it is mainly to remove a portion of the spacing layer 207; wherein the remaining spacing layer 207 covers the side wall of the first columnar structure 204.

In some implementations, as shown in FIG. 12, while removing a portion of the spacing layer 207 on the first region 201, a portion of the spacing layer 207 on the second region 217 is removed; wherein the remaining spacing layer 207 on the second region 217 covers the side wall of the first columnar structure 204 on the second region 217.

In some examples, a portion of the spacing layer 207 can be removed by dry etching process. As shown in FIG. 12, after removing a portion of the spacing layer 207, the remaining spacing layer 207 forms a spacing sidewall structure 220. The first spacing material layer 210 in the spacing sidewall structure 220 covers the side wall of the gate 205. The second spacing material layer 212 in the spacing sidewall structure 220 includes a first portion extending along a thickness direction of the semiconductor layer 202 and a second portion extending along a direction perpendicular to the thickness direction of the semiconductor layer 202. The first portion covers the side wall of the first spacing material layer 210, and the second portion covers the first gate insulation layer 203 on both sides. The third spacing material layer 213 in the spacing sidewall structure 220 covers the side wall of the first portion and the top wall of the second portion.

In an implementation of the present disclosure, after removing a portion of the spacing layer, a mask layer is still retained at the top of the gate, which can provide better protection for the gate. This allows for the improvement of the impact of plasma induced damage on the device when removing a portion of the first gate insulation layer and a portion of the second gate insulation layer in subsequent processes.

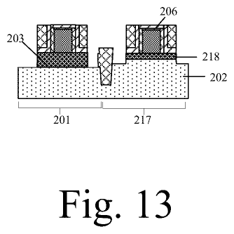

In operation S50, as shown in FIGS. 12 and 13, the first gate insulation layer 203 on both sides of the first columnar structure 204 exposed is removed.

In some implementations, as shown in FIGS. 12 and 13, the removing the first gate insulation layer 203 on both sides of the first columnar structure 204 exposed includes: thinning the first gate insulation layer 203 on both sides of the first columnar structure 204 exposed through a dry etching process; and removing the remaining first gate insulation layer 203 on both sides of the first columnar structure 204 through a wet etching process.

In some implementations, the removing the first gate insulation layer 203 on both sides of the first columnar structure 204 exposed includes: removing the first gate insulation layer 203 on both sides of the first columnar structure 204 exposed through a dry etching process.

It can be understood that in the disclosed implementation, the above two schemes are provided. For the removal of the first gate insulation layer 203 on the first region 201, the first gate insulation layer 203 can be directly removed by dry etching. Alternatively, the first gate insulation layer 203 can be thinned by dry etching first, then the thickness of the thinned first gate insulation layer 203 is relatively thin, and the remaining first gate insulation layer 203 can be removed completely during the wet etching and cleaning process. In addition, the first material layer 208 in the mask layer 206 can also be removed during the wet etching and cleaning process mentioned above.

In the scheme provided in an implementation of the present disclosure, in which scheme the first gate insulation layer 203 is first thinned through dry etching, then the remaining first gate insulation layer 203 is removed completely during the wet etching and cleaning process, the wet etching and cleaning process can be a cleaning treatment performed before forming an electrode layer to form the electrode layer having better contact. The above implementation further removes the first gate insulation layer 203 through the existing wet etching and cleaning operations, fully utilizing resources and saving overall process time.

In some implementations, the removing of a portion of the spacing layer 207 and the thinning treatment of the first gate insulation layer 203 on both sides of the first columnar structure 204 exposed through a dry etching process are carried out in the same process.

It can be understood that in an implementation of the present disclosure, the removing a portion of the spacing layer 207 and the thinning treatment of the first gate insulation layer 203 on both sides of the first columnar structure 204 exposed through a dry etching process can be carried out in the same process, or removing a portion of the spacing layer 207 and removing the first gate insulation layer 203 completely through dry etching directly can be carried out in the same process, which can save process operations and thus save costs.

In some implementations, as shown in FIGS. 12 and 13, while removing the first gate insulation layer 203 on both sides of the first columnar structure 204 exposed on the first region 201, the second gate insulation layer 218 on both sides of the first columnar structure 204 exposed on the second region 217 and a portion of the semiconductor layer 202 on both sides of the first columnar structure 204 on the second region 217 are removed.

It can be understood that in an implementation of the present disclosure, due to the protection by the mask layer 206, the removal of the first gate insulation layer 203 and the removal of the second gate insulation layer 218 can be carried out in the same process, without adding an additional mask for an additional dry etching process to remove the first gate oxide layer separately due to the need to consider the impact of plasma on the gate during the dry etching process. The scheme provided in the implementation of the present disclosure can save process operations, save masks, and thus save costs.

In an implementation of the present disclosure, in the process of removing the first gate insulation layer 203 and the second gate insulation layer 218 through dry etching, due to the thickness of the first gate insulation layer 203 being greater than the thickness of the second gate insulation layer 218, the thickness of the first gate insulation layer 203 is still relatively thick after removing the second gate insulation layer 218. It is desired to continue dry etching to remove the first gate insulation layer 203. Since the top of the gate 205 on both the first and second regions is covered by the mask layer 206, the damage to the gate 205 during the dry etching process can be improved. Due to the exposure of a portion of the second region 217 of the semiconductor layer 202 located on both sides of the second gate insulation layer 218 at this time, a portion of the second region 217 located on both sides of the second gate insulation layer 218 will be consumed, resulting in a top surface of a portion of the second region 217 located on both sides of the second gate insulation layer 218 being lower than a top surface of a portion of the second region 217 covered by the second gate insulation layer 218.

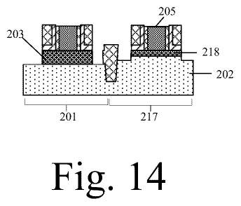

In some implementations, as shown in FIG. 14, the method further includes: removing the mask layer 206 through a wet etching process, after removing the first gate insulation layer 203 on both sides of the first columnar structure 204 exposed.

In some examples, if the first gate insulation layer 203 is removed completely by dry etching to thin first and then wet etching to remove, the removal of the mask layer can be carried out after dry etching of the first gate insulation layer; if the first gate insulation layer 203 is directly removed completely by dry etching, the removal of the mask layer can be carried out after the dry etching of the first gate insulation layer.

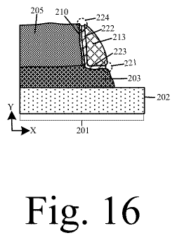

It can be understood that in the implementation of the present disclosure, when removing the second material layer 209 in the mask layer 206 through a wet etching process, due to the fact that the material of the second material layer 209 is the same as that of the second spacing material layer 212, and that a portion of the second spacing material layer 212 in the spacing layer 207 close to the semiconductor layer 202 is exposed, a portion of the second portion of the second spacing material layer 212 close to the semiconductor layer 202 will also be consumed while removing the second material layer 209, as shown in FIG. 16, so that a first recess 221 is formed at the end of the second portion 223 of the second spacing material layer 212 between the first gate insulation layer 203 and the third spacing material layer 213. In addition, after the removal of the second material layer 209 at the top of the gate 205, the end of the first portion of the second spacing material layer 212 is exposed, and a portion of the first portion is also consumed during the wet etching process, as shown in FIG. 16, resulting in a second recess 224 being formed at the top of the spacing sidewall structure.

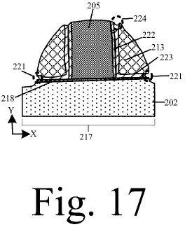

In some examples, as shown in FIG. 17, the first recess 221 also exists on the second region, located at the end of the second portion of the second spacing material layer 212 between the second gate insulation layer 203 and the third spacing material layer 213. The second recess 224 also exists on the second region, located at the top of the spacing sidewall structure, and in some examples, located at the end of the first portion of the second spacing material layer 212.

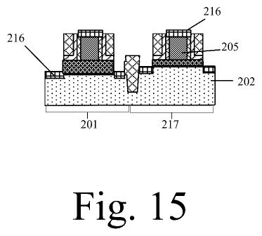

In some implementations, as shown in FIG. 15, the method further includes: forming an electrode layer 216 after removing the first gate insulation layer 203 on both sides of the first columnar structure 204 exposed; wherein the electrode layer 216 covers the top of the gate 205 and the semiconductor layer 202 on both sides of the gate 205.

In some examples, a metal material layer can be formed on the semiconductor layer 202 exposed on both sides of the gate 205 and the top of the gate 205 exposed. The material of the metal material layer, for example, can be metal nickel, and the metal material layer, the semiconductor layer 202, and the gate 205 can be heat treated to form the electrode layer 216 on the top of the gate 205 and on the semiconductor layer 202 on both sides of the gate 205. The material of the electrode layer 216 can be a metal semiconductor compound layer, which can reduce a contact resistance between the source, drain and gate of the ultimately formed transistor and a contact structure.

Based on a concept similar to the formation method of the semiconductor device in the above implementations, as shown in FIGS. 16 to 18, an implementation of the present disclosure further provides a semiconductor device 2000 including a semiconductor structure 200, wherein the semiconductor structure 200 includes: a semiconductor layer 202 with a first region 201 and a first gate insulation layer 203 located on the first region 201; a gate 205 and a spacing sidewall structure 220 located on the first gate insulation layer 203, wherein the spacing sidewall structure 220 covers the side wall of the gate 205, and a first recess 221 exists at a portion of the spacing sidewall structure 220 close to the first gate insulation layer 203.

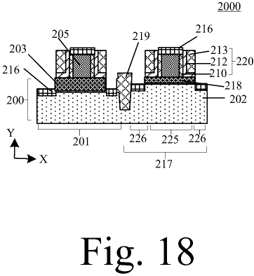

FIG. 17 is a cross-sectional structure diagram of the semiconductor device in the first region. FIG. 18 is a cross-sectional structure diagram of the semiconductor device in the second region. FIGS. 17 and 18 only show portions of the structure as an example.

In some implementations, the semiconductor layer 202 also has a second region 217, wherein the first region 201 and the second region 217 are arranged side by side along a direction perpendicular to a thickness direction of the semiconductor layer 202; the semiconductor structure 200 further includes a second gate insulation layer 218 located on the second region 217, wherein a thickness of the first gate insulation layer 203 is greater than that of the second gate insulation layer 218.

In some examples, the semiconductor layer 202 may include a substrate, which may include a single semiconductor material substrate (such as a silicon (Si) substrate, a germanium (Ge) substrate, etc.), a composite semiconductor material substrate (such as a germanium silicon (SiGe) substrate, etc.), a silicon on insulator (SOI) substrate, a germanium on insulator (GeOI) substrate, etc. For example, the substrate is a silicon substrate. The first region 201 of the semiconductor layer 202 can be a high voltage region, and the second region 217 of the semiconductor layer 202 can be a low voltage region.

In some implementations, the material of the first gate insulation layer 203 includes but is not limited to silicon oxide. The material of the second gate insulation layer 218 includes but is not limited to silicon oxide.

In some implementations, the material of the gate 205 includes but is not limited to polycrystalline silicon.

In some implementations, the size of the first recess 221 along a direction perpendicular to the thickness direction of the semiconductor layer 202 ranges from 1 nm to 10 nm.

The thickness direction of the semiconductor layer in the implementation of the present disclosure can be understood as the Y direction shown in FIG. 18, and the thickness direction perpendicular to the semiconductor layer can be understood as the X direction shown in FIG. 18.

In some implementations, the spacing sidewall structure 220 includes a first spacing material layer 210, a second spacing material layer 212, and a third spacing material layer 213; wherein, the first spacing material layer 210 covers the side wall of the gate 205; the second spacing material layer 212 includes a first portion 222 extending along the thickness direction of the semiconductor layer 202 and a second portion 223 extending along a direction perpendicular to the thickness direction of the semiconductor layer 202, the first portion 222 covers the side wall of the first spacing material layer 210 and the second portion 223 covers the first gate insulation layer 203 on both sides of the gate 205; the third spacing material layer 213 covers the side wall of the first portion 222 and the top wall of the second portion 223; and the first recess 221 is located at the end of the second portion 223 between the first gate insulation layer 203 and the third spacing material layer 213.

In some implementations, the material of the first spacing material layer 210 includes silicon oxide, the material of the second spacing material layer 212 includes silicon nitride, and the material of the third spacing material layer 213 includes silicon oxide.

In some implementations, as shown in FIGS. 16 and 17, a second recess 224 exists at the top of the spacing sidewall structure 220.

In some examples, the second trench is, in some examples, located at the end of the first portion of the second spacing material layer between the first spacing material layer and the third spacing material layer.

In some examples, the size of the second recess 224 along the thickness direction of the semiconductor layer 202 range is 3 nm to 5 nm.

In some implementations, the semiconductor device 2000 further includes: an electrode layer 216; wherein the electrode layer 216 is located on the gate 205 and on the semiconductor layer 202 on both sides of the first gate insulation layer 203.

In some implementations, the material of the electrode layer 216 includes nickel silicide.

In some implementations, the gate 205 and the spacing sidewall structure 220 are further located on the second gate insulation layer 218, and the gates 205 on the first region 201 and the second region 217 are discrete from each other, and the spacing sidewall structures 220 on the first region 201 and the second region 217 are discrete from each other.

In some implementations, the semiconductor device 2000 further includes an isolation structure 219; wherein the isolation structure 219 divides the semiconductor layer 202 into the first region 201 and the second region 217.

In some examples, the material of the isolation structure 219 includes but is not limited to silicon oxide.

In some implementations, the second region 217 includes a first sub-region 225 and a second sub-region 226, wherein the first sub-region 225 is covered by the second gate insulation layer 218, the second sub-region 226 is located on both sides of the first sub-region 225, and a top surface of the first sub-region 225 is higher than a top surface of the second sub-region 226.

In some implementations, the height difference between the top surface of the first sub-region 225 and the top surface of the second sub-region 226 ranges from 5 nm to 15 nm.

The above characteristics related to semiconductor devices have been detailed in the formation methods of semiconductor devices. For simplicity, they will not be repeated here.

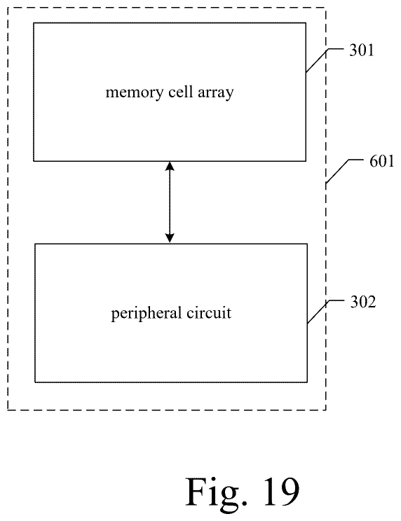

Based on a similar concept for the semiconductor device in the above implementations, as shown in FIG. 19, an implementation of the present disclosure also provides a memory 601, which includes a semiconductor device as described in any of the above implementations.

As shown in FIG. 19, the memory includes a memory cell array 301 and a peripheral circuit 302 coupled to the memory cell array 301, wherein the semiconductor device in any of the above implementations can be a device in the peripheral circuit 302.

Memory 601 can be a 3D NAND flash memory, a random access memory (RAM), etc. The following is illustrated only with reference to an example of a three-dimensional NAND flash memory.

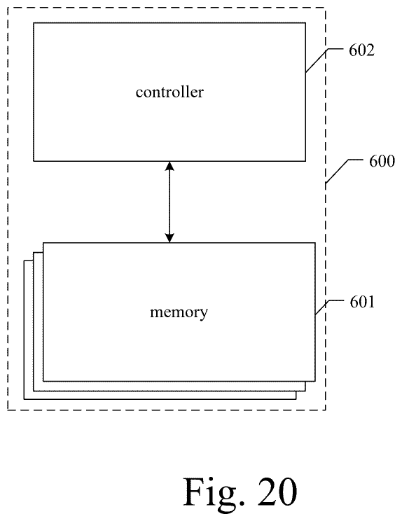

As shown in FIG. 20, an implementation of the present disclosure further provides a memory system 600 including: at least one memory 601 in any of the aforementioned implementations and a controller 602; wherein the controller 602 is coupled to at least one memory 601 and configured to control the memory 601.

In some implementations, the controller 602 and one or more memories 601 can be integrated into various types of storage devices, that is to say, the memory system 600 can be implemented and packaged into different types of terminal electronic products.

In some examples, the memory system 600 can be one of a compact flash card (CFC), a smart media card (SMC), a memory stick (MS), a multi-media card (MMC), such as a RS-MMC, MMC micro, eMMC, etc., an secure digital memory card (SD card), such as a Mini SD card, Micro SD card, SDHC card, etc., a universal flash storage (UFS) card, and a solid state drive (SSD).

In some other examples, the memory system 600 may be placed in a mobile phone, a desktop computer, a laptop, a tablet, a vehicle computer, a game console, a printer, a positioning device, a wearable electronic device, a smart sensor, a virtual reality (VR) device, an augmented reality (AR) device, or any other suitable electronic device with storage therein.

The features disclosed in the several device implementations provided in the present disclosure can be combined arbitrarily without conflict to obtain new device implementations.

The methods disclosed in the several method implementations provided in the present disclosure can be combined arbitrarily without conflict to obtain new method implementations.

The above are only some implementations of the present disclosure, but the scope of protection of the present disclosure is not limited thereto. Any technical personnel skilled in the art can easily think of changes or replacements within the scope of the present disclosure, which should be covered within the scope of protection of the present disclosure. Therefore, the scope of protection of the present disclosure shall be based on the scope of protection of the claims.

What is claimed is:

1. A semiconductor device comprising:
a semiconductor structure which comprises: a semiconductor layer with a first region; and a first gate insulation layer located on the first region; and
a gate and a spacing sidewall structure located on the first gate insulation layer, wherein the spacing sidewall structure covers a side wall of the gate, and a first recess exists at a portion of the spacing sidewall structure close to the first gate insulation layer.

2. The semiconductor device of claim 1, wherein a size of the first recess along a direction perpendicular to a thickness direction of the semiconductor layer ranges from 1 nm to 10 nm.

3. The semiconductor device of claim 1, wherein the spacing sidewall structure comprises a first spacing material layer, a second spacing material layer, and a third spacing material layer, and wherein: the first spacing material layer covers the side wall of the gate; the second spacing material layer comprises a first portion extending along a thickness direction of the semiconductor layer and a second portion extending along a direction perpendicular to the thickness direction of the semiconductor layer, the first portion covers a side wall of the first spacing material layer, and the second portion covers the first gate insulation layer on both sides of the gate; the third spacing material layer covers a side wall of the first portion and a top wall of the second portion; and the first recess is located at an end of the second portion between the first gate insulation layer and the third spacing material layer.

4. The semiconductor device of claim 3, wherein a material of the first spacing material layer comprises silicon oxide, a material of the second spacing material layer comprises silicon nitride, and a material of the third spacing material layer comprises silicon oxide.

5. The semiconductor device of claim 1, wherein a second recess exists at a top of the spacing sidewall structure.

6. The semiconductor device of claim 1, wherein the semiconductor device further comprises:
an electrode layer located on the gate and on the semiconductor layer on both sides of the first gate insulation layer.

7. The semiconductor device of claim 1, wherein the semiconductor layer further has a second region, and the first region and the second region are arranged side by side along a direction perpendicular to a thickness direction of the semiconductor layer; and the semiconductor structure further comprises a second gate insulation layer located on the second region, and a thickness of the first gate insulation layer is greater than that of the second gate insulation layer, wherein the gate and the spacing sidewall structure are further located on the second gate insulation layer, and the gate on the first region and the gate on the second region are discrete from each other, and the spacing sidewall structure on the first region and the spacing sidewall structure on the second region are discrete from each other.

8. The semiconductor device of claim 7, wherein the second region comprises a first sub-region and a second sub-region, the first sub-region is covered by the second gate insulation layer, the second sub-region is located on both sides of the first sub-region, and a top surface of the first sub-region is higher than a top surface of the second sub-region.

9. The semiconductor device of claim 8, wherein a height difference between the top surface of the first sub-region and the top surface of the second sub-region ranges from 5 nm to 15 nm.

10. A memory comprising a semiconductor device, wherein the semiconductor device comprising:
a semiconductor structure which comprises: a semiconductor layer with a first region; and a first gate insulation layer located on the first region; and
a gate and a spacing sidewall structure located on the first gate insulation layer, wherein the spacing sidewall structure covers a side wall of the gate, and a first recess exists at a portion of the spacing sidewall structure close to the first gate insulation layer.

11. A method of forming a semiconductor device, wherein the method comprises:
providing a semiconductor structure which comprises: a semiconductor layer with a first region; and a first gate insulation layer located on the first region;
forming a first columnar structure covering a portion of the first gate insulation layer on the first gate insulation layer, wherein the first columnar structure comprises a gate and a mask layer located on the gate;
forming a spacing layer conformally covering the first columnar structure on the first region and the first gate insulation layer on both sides of the first columnar structure;
removing a portion of the spacing layer, wherein the remaining spacing layer covers a side wall of the first columnar structure; and
removing the first gate insulation layer on both sides of the first columnar structure exposed.

12. The method of claim 11, wherein the mask layer comprises a first material layer and a second material layer located on the first material layer, and wherein a material of the first material layer comprises silicon oxide, and a material of the second material layer comprises silicon nitride.

13. The method of claim 11, wherein the formation method further comprises:
removing the mask layer through a wet etching process after removing the first gate insulation layer on both sides of the first columnar structure exposed.

14. The method of claim 11, wherein the forming a spacing layer conformally covering the first columnar structure on the first region and the first gate insulation layer on both sides of the first columnar structure comprises:
performing a thermal oxidation treatment on a side wall of the gate to form a first spacing material layer on the side wall of the gate, wherein the mask layer, the first spacing material layer, and a remaining portion of the gate form a second columnar structure;
forming a second spacing material layer conformally covering the second columnar structure and the first gate insulation layer on both sides of the second columnar structure; and
forming a third spacing material layer conformally covering the second spacing material layer.

15. The method of claim 11, wherein the removing the first gate insulation layer on both sides of the first columnar structure exposed comprises:
thinning the first gate insulation layer on both sides of the first columnar structure exposed through a dry etching process; and
removing the remaining first gate insulation layer on both sides of the first columnar structure through a wet etching process.

16. The method of claim 15, wherein the removing a portion of the spacing layer and the thinning the first gate insulation layer on both sides of the first columnar structure exposed through a dry etching process are carried out in a same process.

17. The method of claim 11, wherein the forming a first columnar structure covering a portion of the first gate insulation layer on the first gate insulation layer comprises:
forming a gate material layer covering the first gate insulation layer on the first gate insulation layer;
forming a mask material layer covering the gate material layer on the gate material layer; and
etching the mask material layer and the gate material layer to form the first columnar structure.

18. The method of claim 11, wherein the formation method further comprises:
forming an electrode layer after removing the first gate insulation layer on both sides of the first columnar structure exposed, wherein the electrode layer covers a top of the gate and the semiconductor layer on both sides of the gate.

19. The method of claim 11, wherein the semiconductor layer further has a second region, and the first region and the second region are arranged side by side along a direction perpendicular to a thickness direction of the semiconductor layer, and wherein the semiconductor structure further comprises a second gate insulation layer located on the second region, and a thickness of the first gate insulation layer is greater than that of the second gate insulation layer.

20. The method of claim 19, wherein the formation method further comprises:
forming the first columnar structure covering a portion of the second gate insulation layer on the second gate insulation layer while forming the first columnar structure covering the portion of the first gate insulation layer on the first gate insulation layer;
forming the spacing layer conformally covering the first columnar structure on the second region and the second gate insulation layer on both sides of the first columnar structure on the second region while forming the spacing layer conformally covering the first columnar structure on the first region and the first gate insulation layer on both sides of the first columnar structure;
removing a portion of the spacing layer on the second region while removing the portion of the spacing layer on the first region, wherein the remaining spacing layer on the second region covers a side wall of the first columnar structure on the second region; and
removing the second gate insulation layer on both sides of the first columnar structure exposed on the second region and a portion of the semiconductor layer on both sides of the first columnar structure on the second region while removing the first gate insulation layer on both sides of the first columnar structure exposed on the first region.
